(19) United States
(12) Patent Application Publication
(10) Pub. No.: US 2013/0099284 A1
(43) Pub. Date: Apr. 25, 2013

(54) GROUP III-NITRIDE METAL-INSULATOR-SEMICONDUCTOR HETEROSTRUCTURE FIELD-EFFECT TRANSISTORS

(71) Applicants: Hua-Quen Tserng, Dallas, TX (US); Paul Saunier, Dallas, TX (US)

(72) Inventors: Hua-Quen Tserng, Dallas, TX (US); Paul Saunier, Dallas, TX (US)

(73) Assignee: TRIQUINT SEMICONDUCTOR, INC., Hillsboro, OR (US)

(21) Appl. No.: 13/278,084

(22) Filed: Oct. 20, 2011

(51) Int. Cl. H01L 29/778; H01L 21/338

(52) U.S. Cl. 257/194; 438/172; 257/E29.246; 257/E21.403

(57) ABSTRACT

Embodiments of the present disclosure describe apparatuses, methods, and systems of an integrated circuit (IC) device such as, for example, a high electron mobility transistor (HEMT) or metal-insulator-semiconductor field-effect transistor (MISFET), or combinations thereof. The IC device includes a buffer layer formed on a substrate, a barrier layer formed on the buffer layer, the barrier layer including aluminum (Al), nitrogen (N), and at least one of indium (In) and gallium (Ga), a cap layer formed on the barrier layer, the cap layer including nitrogen (N) and at least one of indium (In) and gallium (Ga), and a gate formed on the cap layer, the gate being directly coupled with the cap layer. Other embodiments may also be described and/or claimed.

### FIELD

Embodiments of the present disclosure generally relate to the field of integrated circuits, and more particularly, to a heterostructure field-effect transistor and method of fabrication.

### BACKGROUND

Heterostructure field-effect transistors generally include a heterojunction formed between two semiconductor materials having different bandgaps. High mobility charge carriers may be generated using, for example, a heterojunction of a wide bandgap layer (e.g., n-type donor-supply layer) and a narrow bandgap layer. Current is generally confined to a very narrow channel at an interface of the layers, and flows between source and drain terminals, the current being controlled by a voltage applied to a gate terminal.

Although heterostructure field-effect transistors may demonstrate adequate power performance from Ultra High Frequency (UHF) to millimeter wave frequencies, current devices may encounter challenges with current collapse, gate leakage, and high temperature reliability. In various applications, including, for example, high power radio frequency (RF) switch applications, a device having higher breakdown voltage, lower leakage, and increased reliability over current HEMTs may be desirable.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 schematically illustrates a cross-section view of an integrated circuit (IC) device, according to various embodiments.

FIG. 2 schematically illustrates a cross-section view of another integrated circuit (IC) device, according to various embodiments.

FIG. 3 schematically illustrates a cross-section view of another integrated circuit (IC) device, according to various embodiments.

FIG. 4 schematically illustrates a cross-section view of another integrated circuit (IC) device, according to various embodiments.

FIG. 5 schematically illustrates a cross-section view of another integrated circuit (IC) device, according to various embodiments.

FIG. 6 is a flow diagram of a method for fabricating an integrated circuit device, according to various embodiments.

FIG. 7 schematically illustrates an example system including an IC device, according to various embodiments.

### DETAILED DESCRIPTION

Embodiments of the present disclosure provide structural configurations of an integrated circuit (IC) device such as, for example, a high electron mobility transistor (HEMT) or metal-insulator-semiconductor field-effect transistor (MISFET), or combinations thereof, methods of fabrication, and systems. In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous. The term “coupled” may refer to a direct connection, an indirect connection, or an indirect communication.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other.

In various embodiments, the phrase “a first layer formed on a second layer,” may mean that the first layer is formed over the second layer, and at least a part of the first layer may be in direct contact (e.g., direct physical and/or electrical contact) or indirect contact (e.g., having one or more other layers between the first layer and the second layer) with at least a part of the second layer.

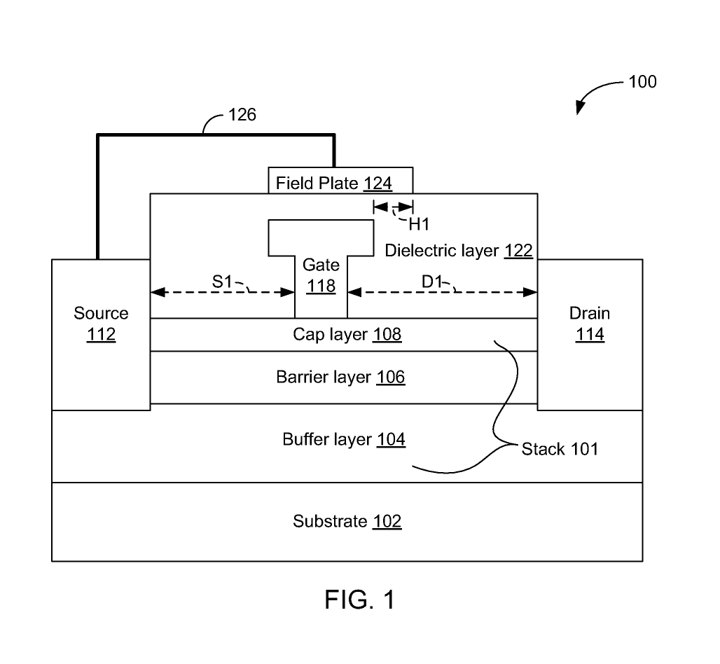

FIG. 1 schematically illustrates a cross-section view of an integrated circuit (IC) device 100, according to various embodiments. The IC device 100 may be, for example, a HEMT device.

The IC device 100 may be fabricated on a substrate 102. The substrate 102 generally includes a support material upon which a stack of layers (or simply “stack 101”) is deposited. In an embodiment, the substrate 102 includes silicon (Si), silicon carbide (SiC), aluminum oxide (Al₂O₃) or “sapphire,” gallium nitride (GaN), and/or aluminum nitride (AlN). Other materials including suitable group II-VI and group III-V semiconductor material systems can be used for the substrate 102 in other embodiments. In an embodiment, the substrate 102 may be composed of any material or combination of materials upon which material of the buffer layer 104 can be epitaxially grown.

The stack 101 formed on the substrate 102 may include epitaxially deposited layers of different material systems that form one or more heterojunctions/heterostructures. The layers of the stack 101 may be formed in situ. That is, the stack 101 may be formed on the substrate 102 in manufacturing equipment (e.g., a chamber) where the constituent layers of the stack 101 are formed (e.g., epitaxially grown) without removing the substrate 102 from the manufacturing equipment.

In one embodiment, the stack 101 of the IC device 100 includes a buffer layer 104 formed on the substrate 102. The buffer layer 104 may provide a crystal structure transition between the substrate 102 and other components (e.g., barrier layer 106) of the IC device 100, thereby acting as a buffer or isolation layer between the substrate 102 and other components of the IC device 100. For example, the buffer layer 104 may provide stress relaxation between the substrate 102 and other lattice-mismatched materials (e.g., the barrier layer 106). The buffer layer 104 may be epitaxially coupled with the substrate 102. In other embodiments, a nucleation layer (not shown) may intervene between the substrate 102 and the buffer layer 104.

In some embodiments, the buffer layer 104 may include a nitride-based material such as, for example, gallium nitride (GaN). The buffer layer 104 may have a thickness from 1 to 2 microns in a direction that is substantially perpendicular to a surface of the substrate 102 upon which the buffer layer 104 is formed. The buffer layer 104 may include other suitable materials and/or thicknesses in other embodiments. The buffer layer 104 may be undoped in some embodiments.

The stack 101 may further include a barrier layer 106 formed on the buffer layer 104. A heterojunction may be formed between the barrier layer 106 and the buffer layer 104. The barrier layer 106 may have a bandgap energy that is greater than a bandgap energy of the buffer layer 104. The barrier layer 106 may be a wider bandgap layer that supplies mobile charge carriers and the buffer layer 104 may be a narrower bandgap layer that provides a pathway for the mobile charge carriers. When in operation (e.g., when a voltage is applied to a gate terminal, hereinafter gate 118), a two-dimensional electron gas (2DEG) may be formed at an interface of the buffer layer 104 and the barrier layer 106 allowing current (e.g., the mobile charge carriers) to flow between a source terminal, hereinafter source 112, and a drain terminal, hereinafter drain 114. In some embodiments, the barrier layer 106 is epitaxially coupled with the buffer layer 104.

The barrier layer 106 may be formed of any of a variety of suitable material systems. The barrier layer 106 may include, for example, aluminum (Al) and nitrogen (N) along with indium (In) and/or gallium (Ga). In one embodiment, the barrier layer 106 may be aluminum gallium nitride (AlₓGa₁₋ₓN), where x is a value between 0 and 1 that represents relative quantities of aluminum and gallium. In embodiments, the value for x is from 0.15 to 0.3. Other values for x can be used in other embodiments.

In embodiments where the barrier layer 106 is AlGaN, the barrier layer 106 may have a thickness of 160 to 300 Angstroms in a direction that is substantially perpendicular to a surface of the buffer layer 104 upon which the barrier layer 106 is formed. The barrier layer 106 may include other suitable materials and/or thicknesses in other embodiments.

In another embodiment, the barrier layer 106 may be indium aluminum nitride (In_{y}Al_{1-y}N), where y is a value between 0 and 1 that represents relative quantities of indium and aluminum. The composition of the barrier layer 106 may complement the composition of the buffer layer 104. For example, in some embodiments, the composition of indium in the barrier layer 106 may be reflected by y=0.17. This indium concentration provides the barrier layer 106 with a lattice structure that matches a lattice structure of the buffer layer 104 when the buffer layer is GaN. Such matching may result in relatively low stress, which may provide the IC device 100 with increased reliability through operation. While variance from a 17% concentration of indium may increase lattice structure mismatch, such variance may also provide desirable operating characteristics for particular embodiments. For example, decreasing the concentration of indium to 13%, for example, may induce more charge (current) but may also increase the stress in the IC device 100. Conversely, increasing the concentration of indium to 21%, for example, may induce less charge but may also reduce the overall stress in the IC device 100. In some embodiments, y has a value from 0.13 to 0.21. Other values for y can be used in other embodiments. Another layer (not shown) having a thickness of about 5 to 20 Angstroms of AlN may be disposed between the barrier layer and the buffer layer for embodiments where the barrier layer 106 is InAlN.

In embodiments where the barrier layer 106 is InAlN, the barrier layer 106 may have a thickness of 30 to 150 Angstroms in a direction that is substantially perpendicular to a surface of the buffer layer 104 upon which the barrier layer 106 is formed. The barrier layer 106 may include other suitable materials and/or thicknesses in other embodiments. For example, other group III materials can be used instead of Al or In. The barrier layer 106 may be undoped in some embodiments.

The stack 101 may further include a cap layer 108 formed on the barrier layer 106. The cap layer 108 may be epitaxially coupled with the barrier layer 106. The cap layer 108 may provide a high resistivity passivation layer and/or a gate insulator/dielectric for the IC device 100. For example, the IC device 100 may be a metal-insulator-semiconductor (MIS) field-effect transistor where the cap layer 108 functions as the insulator of the gate 118. The MIS structure that includes the cap layer 108 may provide an effective switch device for power-switch applications including power conditioning applications such as, for example, Alternating Current (AC)-Direct Current (DC) converters, DC-DC converters, DC-AC converters, and the like. The gate 118 may be capacitively coupled with the barrier layer 106 through the cap layer 108.

The cap layer 108 may be composed of any of a variety of suitable material systems. According to various embodiments, the cap layer 108 may include nitrogen (N) combined with indium (In), aluminum (Al), and/or gallium (Ga). In an embodiment, the cap layer 108 may be aluminum nitride (AlN) or gallium nitride (GaN). Other suitable materials may be used for the cap layer 108 in other embodiments.

The cap layer 108 may be grown at a relatively low temperature (e.g., 500° C. to 600° C.) in some embodiments. For example, AlN or GaN grown at a relatively higher temperature (e.g., 1000° C. to 1100° C.) may result in a material having a more single crystal type lattice structure, which may result in the material having a piezoelectric nature that makes the material more sensitive to surface passivation due to incidental trap formation. Such material characteristics may result in increased current collapse and gate leakage if a cap layer 108 formed at the relatively higher temperature is used in the IC device 100. The lower temperature formation of the cap layer 108 may result in a material having a more polycrystalline lattice structure, thereby reducing trap formation and mitigating current collapse and gate leakage in the IC device 100. In some embodiments, the cap layer 108 includes a polycrystalline material. According to various embodiments, the cap layer 108 formed at the relatively lower temperature has a bandgap energy of 5 to 6 electron volts (eV). The bandgap energy of the cap layer 108 may be greater than the bandgap energy of the barrier layer 106.

The cap layer 108 may have a thickness that is designed for high power, high efficiency, and low gate leakage amplifier applications such as, for example, microwave to millimeter wave power amplifier switch devices for wireless transmission of signals (e.g., RF applications). According to various embodiments, the cap layer 108 has a thickness that is less than 50 Angstroms. A thickness of the cap layer 108 that is greater than about 50 to 100 Angstroms may be too thick for efficient power amplifier operations.

The cap layer 108 as described herein may decrease leakage and/or current collapse and increase a breakdown voltage, forward voltage, idle current drift, and reliability of the IC device 100 relative to an IC device that does not include the cap layer 108 as described herein. The cap layer 108 as described herein may further provide increased linearity (e.g., broader transconductance, decreased gate-to-source capacitance swing) and decreased distortion of the IC device 100 resulting in improved reproduction of amplitude/phase of signals (e.g., including amplitude modulation (AM) to AM conversion and AM to phase modulation (PM) conversion).

The IC device 100 further includes gate 118 formed on the cap layer 108. The gate 118 serves as a connection terminal for the IC device 100. The gate 118 may be directly coupled with the cap layer 108.

The gate 118 may have a trunk or bottom portion that is directly coupled with the cap layer 108 and a top portion that extends away from the trunk portion in opposing directions that are substantially parallel to a surface of the cap layer 108 upon which the gate 118 is fabricated, as can be seen. Such configuration of the trunk portion and top portion of the gate 118 may be referred to as a T-shaped gate. In some embodiments, the gate 118 may be a field-plate gate, which may increase a breakdown voltage and/or reduce an electric field between the gate 118 and the drain 114. The trunk portion of the gate 118 may have a thickness of about 300 to about 1400 Angstroms in a direction that is substantially perpendicular to a surface of the cap layer 108 upon which the trunk portion is formed.

The gate 118 is generally composed of an electrically conductive material such as a metal. In some embodiments, the gate 118 may be nickel (Ni), platinum (Pt), iridium (Ir), molybdenum (Mo), gold (Au), and/or aluminum (Al). In an embodiment, a material including Ni, Pt, Ir, or Mo is disposed in the trunk portion of the gate 118 to provide a gate contact with the cap layer 108 and a material including Au is disposed in the top portion of the gate 118 to ensure conductivity and low resistance of the gate 118. According to various embodiments, the gate 118 is part of a high electron mobility transistor (HEMT) device.

The IC device 100 may include a source 112 and drain 114 formed on the cap layer 108. Each of the source 112 and the drain 114 may extend through the cap layer 108 and the barrier layer 106 into the buffer layer 104, as can be seen. According to various embodiments, the source 112 and the drain 114 are ohmic contacts. The source 112 and the drain 114 may be re-grown contacts that may provide a relatively lower contact resistance than standard grown contacts. In embodiments, the contact resistance of the source 112 and the drain 114 is about 0.01 ohm·mm.

The source 112 and the drain 114 may each be composed of an electrically conductive material such as metal. In an embodiment, each of the source 112 and the drain 114 include titanium (Ti), aluminum (Al), molybdenum (Mo), gold (Au), and/or silicon (Si). Other materials can be used in other embodiments.

In an embodiment, a distance D1 between the drain 114 and the gate 118 is greater than a distance S1 between the source 112 and the gate 118. The distance D1 may be a shortest distance between the drain 114 and the gate 118 and the distance S1 may be a shortest distance between the source 112 and the gate 118 in some embodiments. Providing a shorter distance S1 than distance D1 may increase a gate 118 to drain 114 breakdown voltage and/or reduce source 112 resistance.

A dielectric layer 122 may be formed on the cap layer 108 in some embodiments. The dielectric layer 122 may include, for example, silicon nitride (SiN). Other materials can be used for the dielectric layer 122 in other embodiments. In some embodiments, at least a portion of the dielectric layer 122 coupled with the cap layer 108 is formed by epitaxial deposition during an in situ process that is used to form the stack 101. The dielectric layer 122 may substantially encapsulate the gate 118. The dielectric layer 122 may serve as a passivation layer of the IC device 100.

The IC device 100 may include a field plate 124 formed on the dielectric layer 122 to increase a breakdown voltage and/or reduce an electric field between the gate 118 and the drain 114. The field plate 124 may be electrically coupled with the source 112 using an electrically conductive material 126. The electrically conductive material 126 may include a metal such as, for example, gold (Au) that is deposited as an electrode or trace-like structure on the dielectric layer 122. Other suitable materials may be used for the electrically conductive material 126 in other embodiments.

The field plate 124 generally is composed of an electrically conductive material such as a metal and may include materials described in connection with the gate 118. The field plate 124 may be capacitively coupled with the gate 118 through the dielectric layer 122. In some embodiments, a shortest distance between the field plate 124 and the gate 118 is 1000 to 2000 Angstroms. The field plate 124 may be formed over the gate 118 such that a portion of the field plate 124 is disposed directly over the gate 118 and another portion of the field plate 124 is not formed directly over the gate 118 to provide an overhanging region of the field plate 124, as can be seen. In some embodiments, the overhanging region of the field plate 124 extends beyond an edge of the top portion of the gate 118 by a distance H1. The distance H1 may be 0.2 to 1 micron in some embodiments. Other values for H1 may be used in other embodiments.

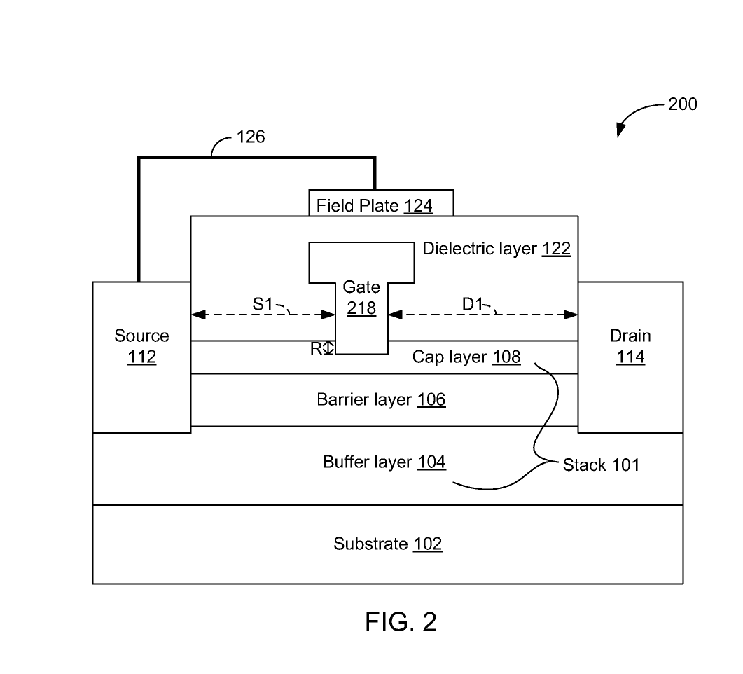

FIG. 2 schematically illustrates a cross-section view of another integrated circuit (IC) device 200, according to various embodiments. The IC device 200 may substantially comport with embodiments described in connection with the IC device 100 of FIG. 1, except that in FIG. 2, a trunk portion of the gate 218 extends into the cap layer 108 by distance R. For example, the cap layer 108 may be recessed by an etch process such as anisotropic etch to remove material from the formed cap layer 108 such that the gate 218 can be formed in the recessed region of the cap layer 108. Other techniques to form the gate 218 such that it extends into the cap layer 108 can be used in other embodiments. Providing a gate 218 that extends into the cap layer 108 may increase a breakdown voltage and/or reduce current collapse in the IC device 200. According to some embodiments, R represents a distance of 10 to 30 Angstroms. R may have other values in other embodiments.

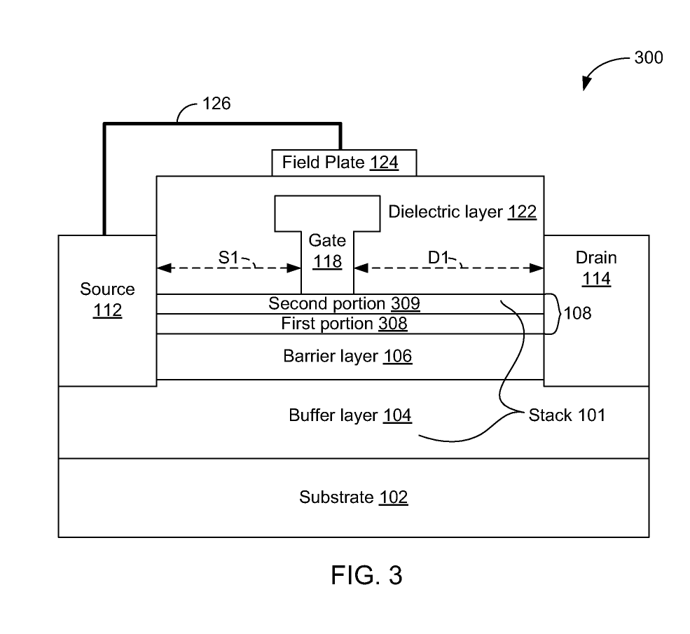

FIG. 3 schematically illustrates a cross-section view of another integrated circuit (IC) device 300, according to various embodiments. The IC device 300 may substantially comport with embodiments described in connection with the IC device 100 of FIG. 1, except that in FIG. 3, the cap layer 108 includes a first portion 308 formed on the barrier layer 106 and a second portion 309 formed on the first portion, as can be seen.

The first portion 308 may be a layer that is, for example, either GaN or AlN formed by a higher temperature process as described herein (e.g., grown at a relatively higher temperature of 1000° C. to 1100° C.). In some embodiments, the first portion 308 includes a substantially or completely single crystal material. The first portion 308 may have a thickness of 20 to 30 Angstroms. Other materials or thicknesses may be used in other embodiments.

The second portion 309 may be a layer that is, for example, either GaN or AlN formed by a lower temperature process as described herein (e.g., grown at a relatively lower temperature of 500° C. to 600° C.). The second portion 309 may serve as an interface or buffer layer to the gate 118 to prevent leakage and reduce disclocation or other defects. In some embodiments, the second portion 309 includes a substantially or completely polycrystalline material. The second portion 309 may have a thickness of 20 to 30 Angstroms. Other materials or thicknesses may be used in other embodiments. The first portion 308 and the second portion 309 may be epitaxially deposited as part of the stack 101 in some embodiments.

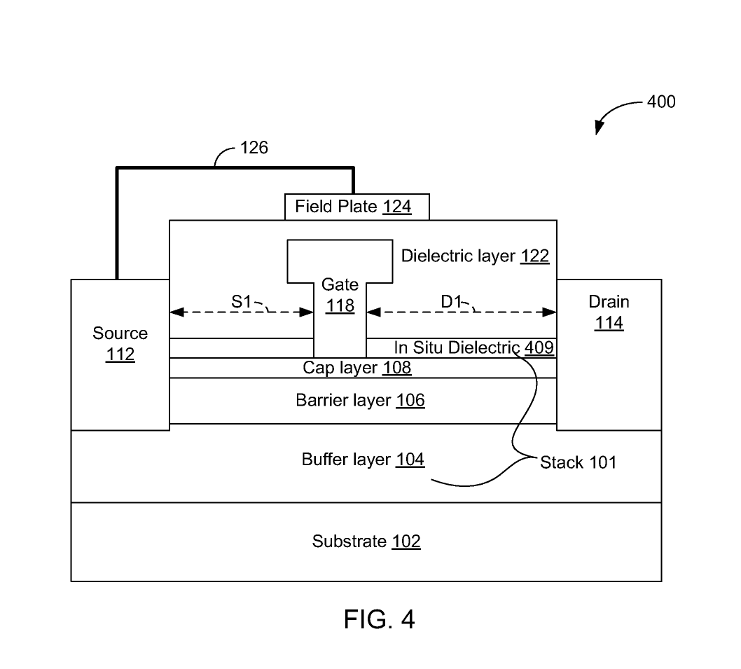

FIG. 4 schematically illustrates a cross-section view of another integrated circuit (IC) device 400, according to various embodiments. The IC device 400 may substantially comport with embodiments described in connection with the IC device 100 of FIG. 1, except that in FIG. 4, the IC device 400 includes an in situ dielectric 409 formed on the cap layer 108, as can be seen.

The in situ dielectric 409 may be a layer of a dielectric material such as, for example, silicon nitride (SiN) or other suitable dielectric material formed on the cap layer 108 as part of the stack 101. The in situ dielectric 409 may have a thickness of 50 to 200 Angstroms in some embodiments. Other thicknesses and/or materials may be used for the in situ dielectric 409 in other embodiments.

In some embodiments, the in situ dielectric 409 is epitaxially deposited on the cap layer 108 and formed in manufacturing equipment (e.g., a chamber) where constituent layers of the stack 101 are formed (e.g., epitaxially grown) without removing the substrate 102 from the manufacturing equipment. The in situ dielectric 409 may be recessed by any suitable process, such as an etch process, to form an opening such that the gate 118 can be formed on the cap layer 108, as can be seen. The dielectric layer 122 may be deposited subsequent to formation of the gate 118 in a process that is extrinsic to the in situ process used to form the in situ dielectric 409. The in situ dielectric 409 may reduce contamination and/or provide an interface that reduces trap density in the IC device 400.

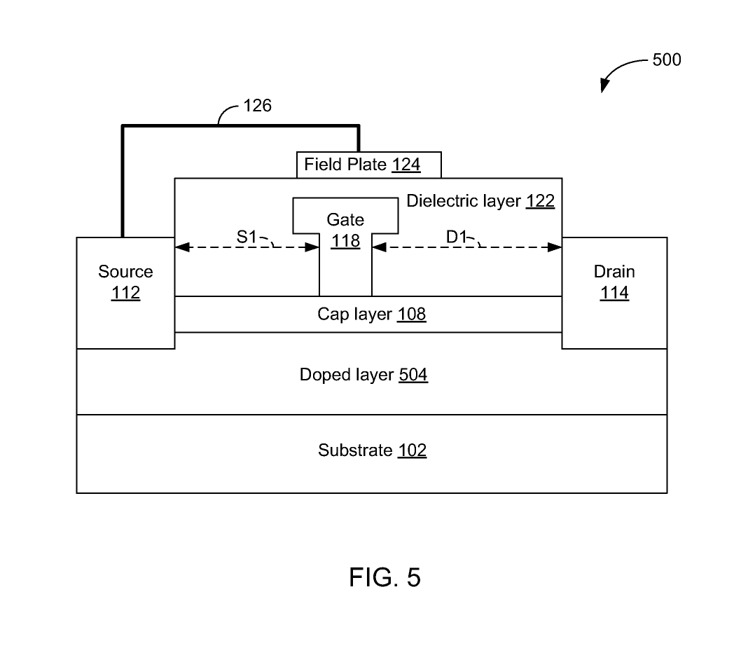

FIG. 5 schematically illustrates a cross-section view of another integrated circuit (IC) device 500, according to various embodiments. The IC device 500 includes a doped layer 504 formed on the substrate 102. The doped layer 504 can include a variety of materials including, for example, the materials described for the substrate 102 in connection with the IC device 100 of FIG. 1. In various embodiments, the doped layer 504 is doped with an impurity such as n-type silicon (Si). The doped layer 504 may have a thickness of 500 to 1500 Angstroms. Other suitable dopants, materials, and/or thicknesses can be used for the doped layer 504 in other embodiments. The remaining features of the IC device 500 in FIG. 5 may comport with embodiments already described in connection with the IC device 100 of FIG. 1.

The embodiments described in connection with the IC devices 100, 200, 300, 400, and/or 500 may be suitably combined in various embodiments. For example, the in situ dielectric 409 of FIG. 4 may be formed on the cap layer 108 having the first portion 308 and the second portion 309 of FIG. 3 and/or the gate 218 of FIG. 2 may be formed to extend into the cap layer 108 of FIG. 3 or 4.

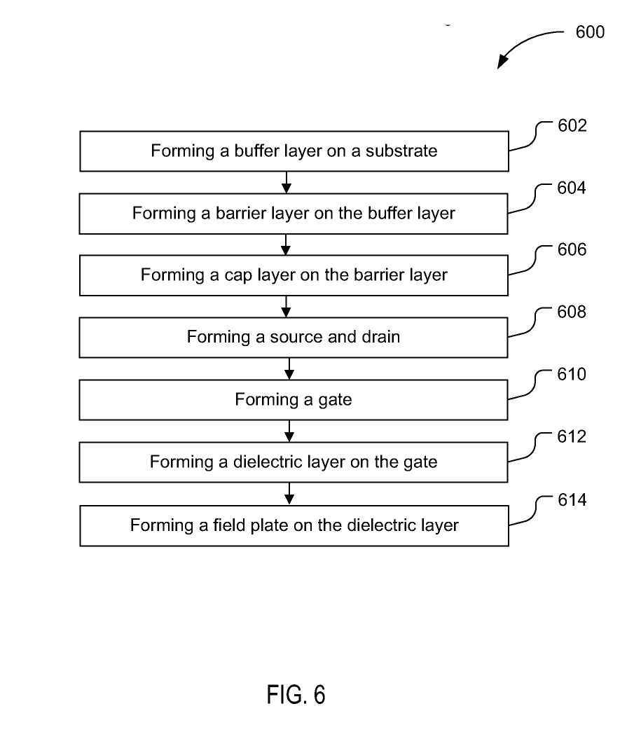

FIG. 6 is a flow diagram of a method 600 for fabricating an integrated circuit device (e.g., the IC device 100, 200, 300, or 400 of respective FIG. 1, 2, 3, or 4), according to various embodiments. The method 600 includes forming a buffer layer (e.g., buffer layer 104 of FIG. 1) on a substrate (e.g., substrate 102 of FIG. 1) at 602, forming a barrier layer (e.g., barrier layer 106 of FIG. 1) on the buffer layer at 604, and forming a cap layer (e.g., cap layer 108 of FIG. 1, 2, 3, or 4) on the barrier layer at 606. Other layers may be formed to intervene between these layers in various embodiments.

According to various embodiments, each of the buffer layer, the barrier layer, and the cap layer is epitaxially deposited by molecular beam epitaxy (MBE), atomic layer epitaxy (ALE), chemical beam epitaxy (CBE) and/or metal-organic chemical vapor deposition (MOCVD). The buffer layer, the barrier layer, and/or the cap layer may be formed according to embodiments already described in connection with FIGS. 1-4. The buffer layer, the barrier layer, and the cap layer may be part of a stack of layers (e.g., stack 101 of FIG. 1) formed using an in situ process as described herein. Other suitable deposition techniques can be used in other embodiments. Materials and/or thicknesses for the layers of the stack may comport with embodiments already described in connection with the IC devices 100, 200, 300, and 400 of respective FIGS. 1, 2, 3, and 4.

At 608, the method 600 may further include forming a source (e.g., source 112 of FIG. 1) and drain (e.g., drain 114 of FIG. 1). The source and drain may be formed on the cap layer in various embodiments. In an embodiment, materials such as one or more metals are deposited on the cap layer in an area where the source and drain are to be formed using, e.g., an evaporation process. The materials used to form the source and the drain may include metals deposited in the following order: titanium (Ti) followed by aluminum (Al), which is followed by molybdenum (Mo), which is followed by titanium (Ti), which is followed by gold (Au). The deposited materials may be heated (e.g., to about 850° C. for about 30 seconds using a rapid thermal anneal process) to cause the materials to penetrate and fuse with underlying material of the cap layer, the barrier layer, and/or the buffer layer. In embodiments, each of the source and the drain extends through the cap layer and into the buffer layer. A thickness of the source and the drain can be 1000 to 2000 Angstroms. Other thicknesses for the source and the drain can be used in other embodiments.

The source and the drain may be formed by a re-growth process to provide ohmic contacts having a reduced contact resistance or reduced on-resistance. In the re-growth process, material of the cap layer, the barrier layer, and/or the buffer layer is selectively removed (e.g., etched) in areas where the source and the drain are to be formed. A highly doped material (e.g., n++ material) is deposited in the areas where the layers have been selectively removed. The highly doped material of the source and drain may be a similar material as the material used for the buffer layer 104 or barrier layer 106. For example, in a system where the buffer layer includes GaN, a GaN-based material that is highly doped with silicon (Si) may be epitaxially deposited in the selectively removed areas to a thickness of 400 to 700 Angstroms. The highly doped material can be epitaxially deposited by molecular beam epitaxy (MBE), atomic layer epitaxy (ALE), chemical beam epitaxy (CBE), or metal-organic chemical vapor deposition (MOCVD), or suitable combinations thereof. Other materials, thicknesses, or deposition techniques for the highly doped material can be used in other embodiments. One or more metals including, e.g., titanium (Ti) and/or gold (Au) can be formed/deposited on the highly doped material at a thickness of 1000 Angstroms to 1500 Angstroms using, e.g., a lift-off process. Other materials, thicknesses, and/or techniques for the one or more metals can be used in other embodiments.

In some embodiments, the source and the drain may be formed by an implantation process that uses implantation techniques to introduce an impurity (e.g., silicon) to provide a highly doped material in the source and the drain. After implantation, the source and the drain are annealed at a high temperature (e.g., 1100-1200° C.). The re-growth process may preferably avoid the high temperature associated with the post-implantation anneal.

At 610, the method 600 may further include forming a gate (e.g., the gate structure 118 of FIG. 1). The gate may be formed on the cap layer by depositing an electrically conductive material on the cap layer. The gate material can be deposited by any suitable deposition process including, for example, evaporation, atomic layer deposition (ALD) and/or chemical vapor deposition (CVD). In an embodiment where the gate is a T-shaped gate, a trunk portion or top portion of the T-gate may be formed by metal deposition/etch processes or a lift-off process.

At 612, the method 600 further includes forming a dielectric layer (e.g., the dielectric layer 122 of FIG. 1) on the gate. The dielectric layer may be formed by depositing a dielectric material on the gate and/or the cap layer using any suitable deposition technique.

At 614, the method 600 further includes forming a field plate (e.g., the field plate 124 of FIG. 1) on the dielectric layer. The field plate may be formed by depositing an electrically conductive material on the dielectric layer using any suitable deposition technique. Patterning processes such as lithography and/or etch processes can be used to selectively remove portions of the deposited electrically conductive material to form the field plate. Other suitable techniques may be used in other embodiments. Similar techniques as described in connection with method 600 may be performed to fabricate the IC device 500 of FIG. 5.

Various operations are described as multiple discrete operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

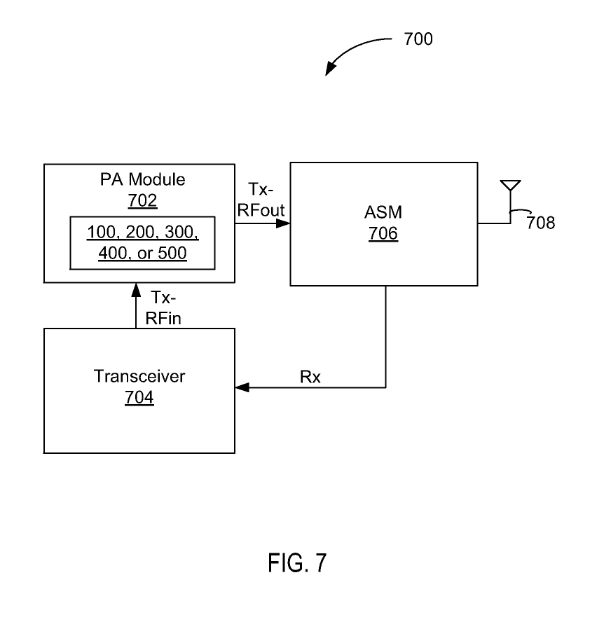

Embodiments of an IC device (e.g., the IC device 100, 200, 300, 400, or 500) described herein, and apparatuses including such IC device 100, may be incorporated into various other apparatuses and systems. A block diagram of an example system 700 is illustrated in FIG. 7. As illustrated, the system 700 includes a power amplifier (PA) module 702, which may be a Radio Frequency (RF) PA module in some embodiments. The system 700 may include a transceiver 704 coupled with the power amplifier module 702 as illustrated. The power amplifier module 702 may include an IC device (e.g., the IC device 100, 200, 300, 400, or 500) described herein.

The power amplifier module 702 may receive an RF input signal, RFin, from the transceiver 704. The power amplifier module 702 may amplify the RF input signal, RFin, to provide the RF output signal, RFout. The RF input signal, RFin, and the RF output signal, RFout, may both be part of a transmit chain, respectively noted by Tx-RFin and Tx-RFout in FIG. 7.

The amplified RF output signal, RFout, may be provided to an antenna switch module (ASM) 706, which effectuates an over-the-air (OTA) transmission of the RF output signal, RFout, via an antenna structure 708. The ASM 706 may also receive RF signals via the antenna structure 708 and couple the received RF signals, Rx, to the transceiver 704 along a receive chain.

In various embodiments, the antenna structure 708 may include one or more directional and/or omnidirectional antennas, including, e.g., a dipole antenna, a monopole antenna, a patch antenna, a loop antenna, a microstrip antenna or any other type of antenna suitable for OTA transmission/reception of RF signals.

The system 700 may be any system including power amplification. The IC device (e.g., the IC device 100, 200, 300, 400, or 500) may provide an effective switch device for power-switch applications including power conditioning applications such as, for example, Alternating Current (AC)-Direct Current (DC) converters, DC-DC converters, DC-AC converters, and the like. In various embodiments, the system 700 may be particularly useful for power amplification at high radio frequency power and frequency. For example, the system 700 may be suitable for any one or more of terrestrial and satellite communications, radar systems, and possibly in various industrial and medical applications. More specifically, in various embodiments, the system 700 may be a selected one of a radar device, a satellite communication device, a mobile handset, a cellular telephone base station, a broadcast radio, or a television amplifier system.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims and the equivalents thereof.

What is claimed is:

1. An apparatus comprising:
a buffer layer formed on a substrate;
a barrier layer formed on the buffer layer, the barrier layer including aluminum (Al), nitrogen (N), and at least one of indium (In) or gallium (Ga);
a cap layer formed on the barrier layer, the cap layer including nitrogen (N) and at least one of indium (In) or gallium (Ga); and
a gate formed on the cap layer, the gate being directly coupled with the cap layer.

2. The apparatus of claim 1, wherein:
the cap layer is polycrystalline gallium nitride (GaN) or polycrystalline aluminum nitride (AlN); and
the cap layer has a thickness of 50 Angstroms or less.

3. The apparatus of claim 1, wherein:
the cap layer has a first bandgap energy that is greater than 5 electron volts (eV);
the barrier layer has a second bandgap energy that is less than the first bandgap energy; and
the buffer layer has a third bandgap energy that is less than the second bandgap energy.

4. The apparatus of claim 1, wherein:
the barrier layer is epitaxially coupled with the buffer layer; and
the cap layer is epitaxially coupled with the barrier layer.

5. The apparatus of claim 1, wherein:
the buffer layer includes gallium nitride (GaN); and
the buffer layer has a thickness of 1 micron to 2 microns.

6. The apparatus of claim 5, wherein the barrier layer includes aluminum gallium nitride (AlₓGa₁₋ₓN), where x is a value from 0.15 to 0.3 that represents relative quantities of aluminum and gallium.

7. The apparatus of claim 5, wherein the barrier layer includes indium aluminum nitride (In_{y}Al_{1-y}N), where y is a value from 0.13 to 0.21 that represents relative quantities of indium and aluminum.

8. The apparatus of claim 1, wherein the gate extends at least 5 Angstroms into the cap layer.

9. The apparatus of claim 1, wherein:
the cap layer includes a first portion substantially having a single crystal material, the first portion being formed on and directly coupled with the barrier layer; and
the cap layer includes a second portion substantially having a polycrystalline material, the second portion being formed on and directly coupled with the first portion.

10. The apparatus of claim 1, further comprising:
a dielectric layer epitaxially coupled with the cap layer.

11. The apparatus of claim 1, wherein:
the gate is a T-shaped field plate gate; and
the gate includes nickel (Ni), platinum (Pt), iridium (Ir), molybdenum (Mo), or gold (Au).

12. The apparatus of claim 1, further comprising:
a source coupled with the cap layer; and
a drain coupled with the cap layer, wherein each of the source and the drain extend through the cap layer and the barrier layer into the buffer layer, the source is an ohmic contact, the drain is an ohmic contact, and a shortest distance between the drain and the gate is greater than a shortest distance between the source and the gate.

13. The apparatus of claim 12, further comprising:
the substrate, the substrate including silicon (Si), silicon carbide (SiC), sapphire (Al₂O₃), gallium nitride (GaN), or aluminum nitride (AlN);
a dielectric layer formed on the cap layer, the dielectric layer substantially encapsulating the gate; and
a field plate formed on the dielectric layer over the gate, the field plate being electrically coupled with the source.

14. The apparatus of claim 1, wherein:
the cap layer is a gate dielectric such that the gate is capacitively coupled with the barrier layer through the cap layer; and
the gate is part of a high electron mobility transistor (HEMT) switch device for a power amplifier application.

15. A method comprising:
forming a buffer layer on a substrate;
forming a barrier layer on the buffer layer, the barrier layer including aluminum (Al), nitrogen (N), and at least one of indium (In) or gallium (Ga);
forming a cap layer on the barrier layer, the cap layer including nitrogen (N) and at least one of indium (In) or gallium (Ga); and
forming a gate on the cap layer, the gate being directly coupled with the cap layer.

16. The method of claim 15, wherein each of the buffer layer, the barrier layer, and the cap layer is formed by epitaxial deposition using molecular beam epitaxy (MBE), atomic layer epitaxy (ALE), chemical beam epitaxy (CBE) or metal-organic chemical vapor deposition (MOCVD).

17. The method of claim 15, wherein:
the cap layer is formed by epitaxially depositing gallium nitride (GaN) or aluminum nitride (AlN) at a temperature from 500° C. to 600° C.; and
the cap layer is formed to have a thickness of 50 Angstroms or less.

18. The method of claim 15, wherein:
the cap layer has a first bandgap energy that is greater than 5 electron volts (eV);
the barrier layer has a second bandgap energy that is less than the first bandgap energy; and
the buffer layer has a third bandgap energy that is less than the second bandgap energy.

19. The method of claim 15, wherein:
the barrier layer is formed by epitaxially depositing the barrier layer on the buffer layer; and
the cap layer is formed by epitaxially depositing the cap layer on the barrier layer.

20. The method of claim 15, further comprising:
forming a source and a drain on the cap layer;
forming a dielectric layer to substantially encapsulate the gate; and
forming a field plate on the dielectric layer, the field plate being disposed over the gate.
